(19) United States
(12) Patent Application Publication
(10) Pub. No.: US 2025/0191970 A1
(43) Pub. Date: Jun. 12, 2025

(54) FULLY SELF-ALIGNED VIAS USING A HARDMASK AND ANTISPACERS

(71) Applicant: Tokyo electron Limited, Tokyo (JP)

(72) Inventors: David Power, Albany, NY (US); David Conklin, Saratoga Springs, NY (US)

(21) Appl. No.: 18/532,873

(22) Filed: Dec. 7, 2023

(51) Int. Cl. H01L 21/768; H01L 21/033; H01L 23/522

(52) U.S. Cl. CPC H01L 21/76816; H01L 21/0337; H01L 21/76877; H01L 23/5226

(57) ABSTRACT

A method of patterning a substrate includes forming a hardmask over an underlying layer supported by a substrate, forming antispacer trenches over the hardmask, and forming fully self-aligned vias (FSAVs) extending from the hardmask into the underlying layer. The hardmask includes hardmask line features defining hardmask trenches extending in a first direction. The antispacer trenches extend in a second direction nonparallel to the first direction. The FSAVs extend into the underlying layer at intersections of the hardmask trenches and the antispacer trenches. The FSAVs are self-aligned on two sides by sidewalls of the hardmask trenches and self-aligned on the remaining sides by sidewalls of the antispacer trenches.

### TECHNICAL FIELD

The present invention relates generally via formation, and, in particular embodiments, to structures and methods of forming vias that are self-aligned on all sides.

### BACKGROUND

The formation of microscale and nanoscale structures within a workpiece, such as within microelectronic workpieces, involves a series of processing techniques that include the formation, patterning, and removal of several layers of material on a substrate. Frequently, access from an upper layer to a lower layer (e.g., through one or more intermediate layers) is required. To accomplish this, vias may be formed through the intermediate layers by removing material in predefined locations through a patterned layer. For example, etching processes (e.g., dry etching, wet etching, plasma etching, etc.) may be used to remove exposed regions of material in the intermediate layers while the patterned layer protects unexposed regions.

Vias may be used to form complex three-dimensional (3D) structures by providing vertical connections (e.g., electrical connections) between layers. As each layer is formed, new structures must be aligned with structures of the existing layers. This alignment is particularly important for via formation to ensure that the vias formed through the intermediate layers line up with the desired structures of the lower layer. However, alignment can be challenging, especially for small via dimensions and thick intermediate layers (e.g., high aspect ratios). Factors such as feature size and process variation may cause overlay errors that negatively impact device performance. For example, vias that are misaligned may make no contact or only make partial contact with desired features of the lower layer.

Lithographic processes may be used to form the patterned layers that define the exposed regions for via formation. Photolithography makes up one broad category of lithographic processes. To form patterned layers using photolithography, a photosensitive layer is exposed to light through a photomask containing a two-dimensional (2D) pattern. The specific type of photolithography may be selected based on the desired feature size and includes ultraviolet (UV) lithography, deep ultraviolet (DUV) lithography, and extreme ultraviolet (EUV) lithography. Mask steps reduce throughput, increase complexity, and increase cost. For example, there is typically a high cost associated with fabricating photomasks (and multiple photomasks may be needed for each mask step). Photomasks also become more and more expensive as feature sizes are decreased (e.g., as the type of photolithography becomes more complex). That is, UV photomasks are less expensive than DUV photomasks, which are in turn less expensive than EUV photomasks, and so on.

Therefore, structures and methods of forming vias that improve via alignment and/or decrease the number of mask steps while enabling high aspect ratios and small features sizes are desirable.

### SUMMARY

In accordance with an embodiment of the invention, a method of patterning a substrate includes forming a hardmask over an underlying layer supported by a substrate where the hardmask includes hardmask line features defining hardmask trenches extending in a first direction, forming antispacer trenches over the hardmask where the antispacer trenches extend in a second direction nonparallel to the first direction, and forming fully self-aligned vias (FSAVs) extending from the hardmask into the underlying layer at intersections of the hardmask trenches and the antispacer trenches. The FSAVs are self-aligned on two sides by sidewalls of the hardmask trenches and self-aligned on the remaining sides by sidewalls of the antispacer trenches.

In accordance with another embodiment of the invention, a method of patterning a substrate includes forming a hardmask over an underlying layer supported by a substrate where the hardmask includes hardmask line features defining hardmask trenches extending in a first direction, forming antispacer trenches over the hardmask where the antispacer trenches extend in a second direction nonparallel to the first direction, forming FSAVs extending from the hardmask through the underlying layer to the substrate at intersections of the hardmask trenches and the antispacer trenches. The FSAVs are self-aligned on two sides by sidewalls of the hardmask trenches and self-aligned on the remaining sides by sidewalls of the antispacer trenches. The method further includes forming fully self-aligned contacts electrically coupled to the substrate by forming a conductive layer in the hardmask trenches and the FSAVs.

In accordance with still another embodiment of the invention, a patterned substrate includes a substrate, a dielectric layer disposed on the substrate, a hardmask disposed on the dielectric layer, antispacer trenches disposed over the hardmask and the dielectric layer, and FSAVs etched into the dielectric layer. The hardmask includes hardmask line features defining hardmask trenches extending in a first direction. Each of the antispacer trenches extend in a second direction nonparallel to the first direction and are defined by a patterned photoresist on a first side and an overcoat on an opposing second side. The FSAVs are etched into the dielectric layer using the hardmask, the patterned photoresist, and the overcoat as an etch mask. The FSAVs are self-aligned on two sides by sidewalls of the hardmask trenches and self-aligned on the remaining sides by sidewalls of the antispacer trenches.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate an example patterned substrate including fully self-aligned vias (FSAVs) passing through an underlying layer using antispacer trenches formed across hardmask trenches underlying a relief pattern and a developed overcoat where FIG. 1A shows the patterned substrate before a stripping step and FIG. 1B shows the patterned substrate after the stripping step in accordance with embodiments of the invention;

FIGS. 2A-2I illustrate an example process flow for patterning a substrate to form FSAVs passing through an underlying layer using antispacer trenches formed across hardmask trenches where FIG. 2A shows a hardmask patterning step, FIG. 2B shows a lithography step, FIG. 2C shows an intermediate layer formation step, FIG. 2D shows an acid diffusion step, FIG. 2E shows an intermediate layer removal step, FIG. 2F shows an overcoat formation step, FIG. 2G shows a development step, FIG. 2H shows an FSAV etching step, and FIG. 2I shows a stripping step in accordance with embodiments of the invention;

FIG. 3 shows a magnified three-dimensional view of an example patterned substrate including FSAVs passing through an underlying layer using antispacer trenches formed across hardmask trenches underlying a relief pattern and a developed overcoat in accordance with embodiments of the invention;

FIGS. 4A-4D illustrate another example process flow for patterning a substrate to form FSAVs passing through an underlying layer using antispacer trenches formed across hardmask trenches where FIG. 4A shows a lithography step, FIG. 4B shows an overcoat formation step, FIG. 4C shows an acid diffusion step, and FIG. 4D shows a development step in accordance with embodiments of the invention;

FIGS. 5A-5D illustrate an example process flow for patterning a substrate to form FSAV contacts passing through an underlying layer using antispacer trenches formed across hardmask trenches where FIG. 5A shows a trench etching step, FIG. 5B shows a barrier deposition step, FIG. 5C shows a plating step, FIG. 5D shows a planarization step in accordance with embodiments of the invention;

FIG. 6 illustrates an example method of patterning a substrate to form FSAVs in accordance with embodiments of the invention; and

FIG. 7 illustrates an example method of patterning a substrate to form FSAV contacts in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

There are many challenges to achieving the required alignment accuracy when forming vias, such as small feature sizes, non-uniform processing (e.g., etching), high aspect ratios, high process complexity, and process variation from factors such as material inhomogeneity, temperature and pressure differences, etc. Self-aligned fabrication processes use an existing structure of the substrate to define a boundary of a new structure (in this case, vias). Because the existing structures defining the boundary of the new structures are already present on the substrate, there is no alignment error associated with the boundary. For this reason, self-aligned fabrication processes can be used to alleviate some or all of the difficulties associated with alignment of that boundary. The existing structure may be a pattern material (e.g., a metal layer) that can be used as a mask. Additional material or layers may also be formed as the existing structures, such as sacrificial layers or spacers.

Fully self-aligned structures have boundaries that are all defined by existing structures. However, fully-self-aligned structures, such as fully-self-aligned vias (FSAVs), can be difficult to achieve for a variety of reasons. For example, conventional self-alignment techniques such as recessed etching and area selective atomic layer deposition (ALD) still use underlying line structures as the basis for the self-alignment. Therefore, only one direction (i.e., two edges) of the vias are self-aligned. Moreover, while area selective ALD can overcome some self-alignment issues but it may only address the chamfer on the non-self-aligned (NSAV) edge at the bottom of the via/contact hole.

One direction (i.e., two opposing sides) of a self-aligned structure may be self-aligned by a patterned layer that already exists on the substrate and is also used for a different purpose. Examples may include a hardmask used to form metal lines, existing gate structures, etc. Another patterned layer may be necessary to provide self-alignment for the remaining direction of the self-aligned structure (e.g., the remaining two opposing sides of a via). This layer may be sacrificial since the desired via locations may differ from the pattern of other available structures. The sacrificial layer may be formed using an additional photomask or a selective area deposition process, both of which increase cost and complexity.

In various embodiments, a method of patterning a substrate includes forming a hardmask (e.g., including a metal, such as titanium nitride (TiN), or amorphous carbon, or another suitable material) over an underlying layer (e.g., one or more intermediate layers, such as a dielectric layer) supported by a substrate (e.g., a semiconductor substrate, such as silicon), forming antispacer trenches over the hardmask, and forming fully self-aligned vias (FSAVs) extending from the hardmask into the underlying layer at intersections of the hardmask trenches and the antispacer trenches. Specifically, the hardmask includes hardmask line features that extend in a first direction while the antispacer trenches extend in a second direction that nonparallel to the first direction (i.e., resulting in the intersection of the hardmask trenches and the antispacer trenches). Thus, the FSAVs are self-aligned on two sides by sidewalls of the hardmask trenches and self-aligned on the remaining sides by sidewalls of the antispacer trenches.

The antispacer trenches may be formed using a relief pattern than is formed over the hardmask. Acid may be diffused either into the relief pattern to increase the solubility of the outer regions of the relief pattern or acid may be diffused from the relief pattern into an overcoat to increase the solubility of regions of the overcoat adjacent to the relief pattern. The regions of increased solubility may then be removed without removing the relief pattern or the overcoat to form the antispacer trenches. The regions of increased solubility may be referred to as antispacers because their positioning directly adjacent to the existing relief pattern is dependent positioning of the relief pattern, but the antispacers are selectively removed after formation rather than the relief pattern.

The embodiments described herein may have the advantages of forming FSAVs without the use of either an additional photomask or a selective area deposition process, thereby reducing fabrication cost and complexity. In some cases, throughput may also advantageously be increased (e.g., by eliminating the use of additional tools, reducing complexity, or reducing the number or duration of necessary steps). A further advantage may be cost reduction for achieving a desired pitch enabled by pitch splitting from the antispacer process. That is, the minimum achievable pitch of a photomask used to form a relief pattern may be split (i.e., halved) to achieve a smaller pitch by using the relief pattern to form antispacer trenches. Thus, a lower cost photomask can be used to achieve the smaller pitch.

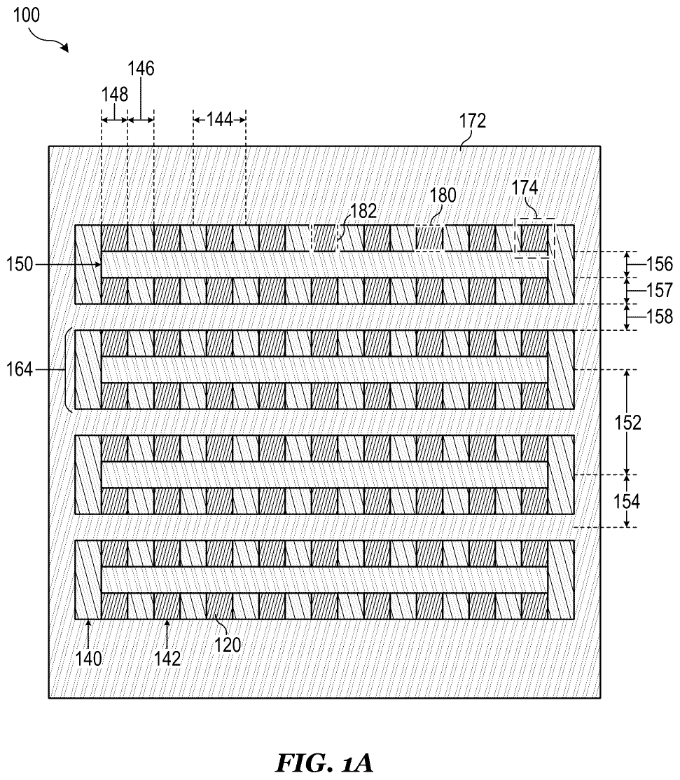

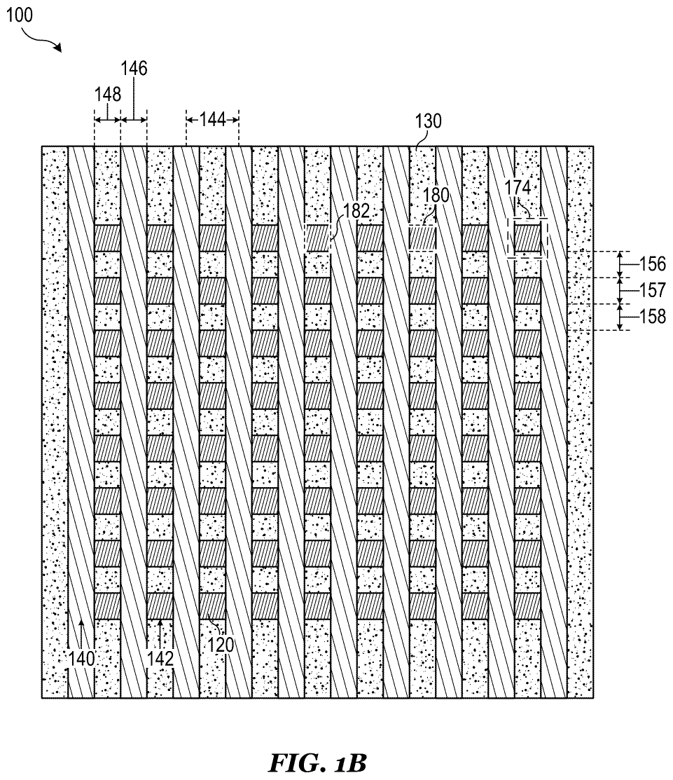

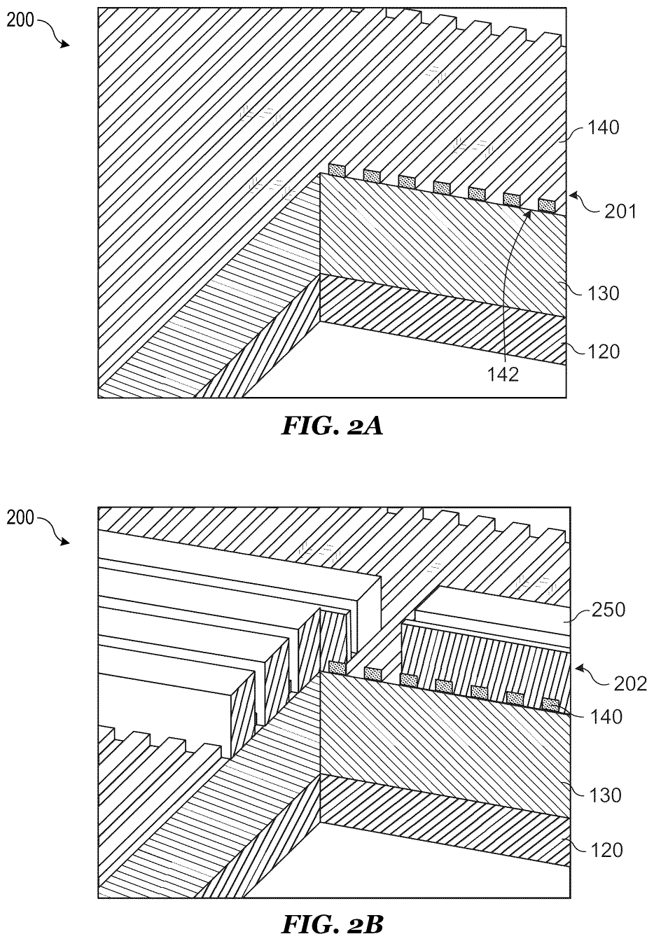

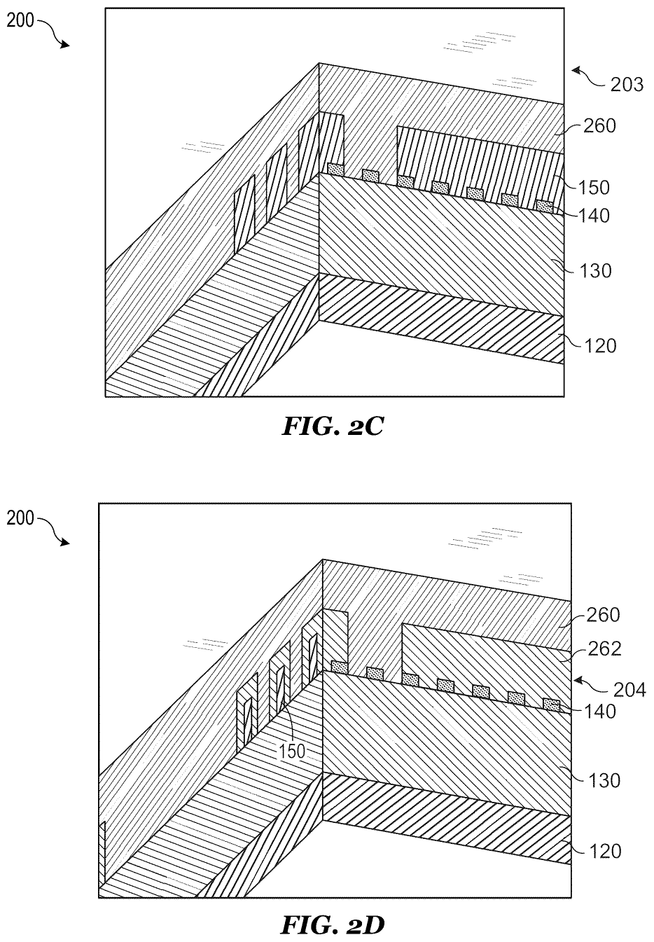

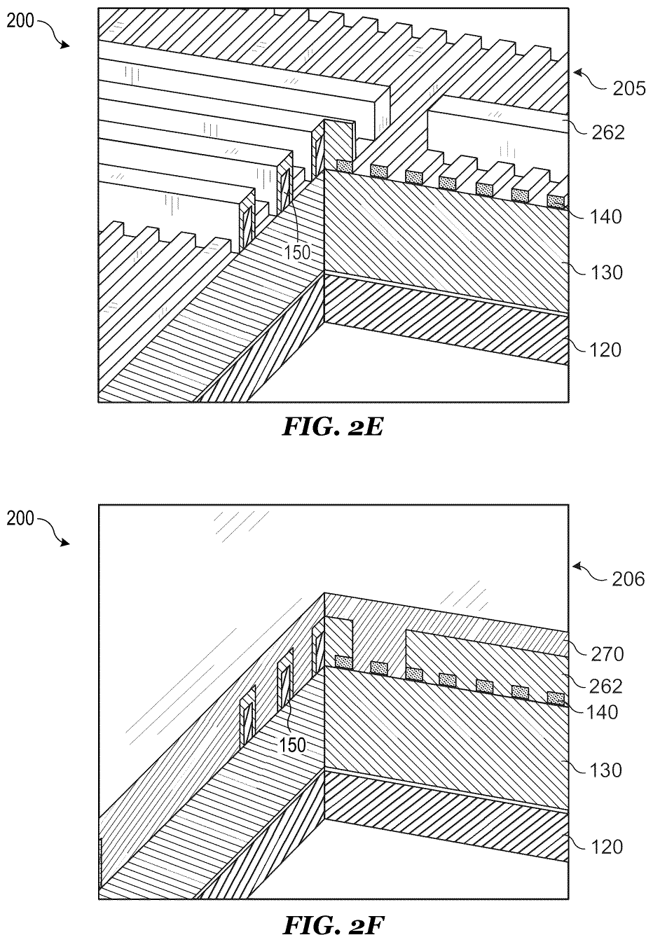

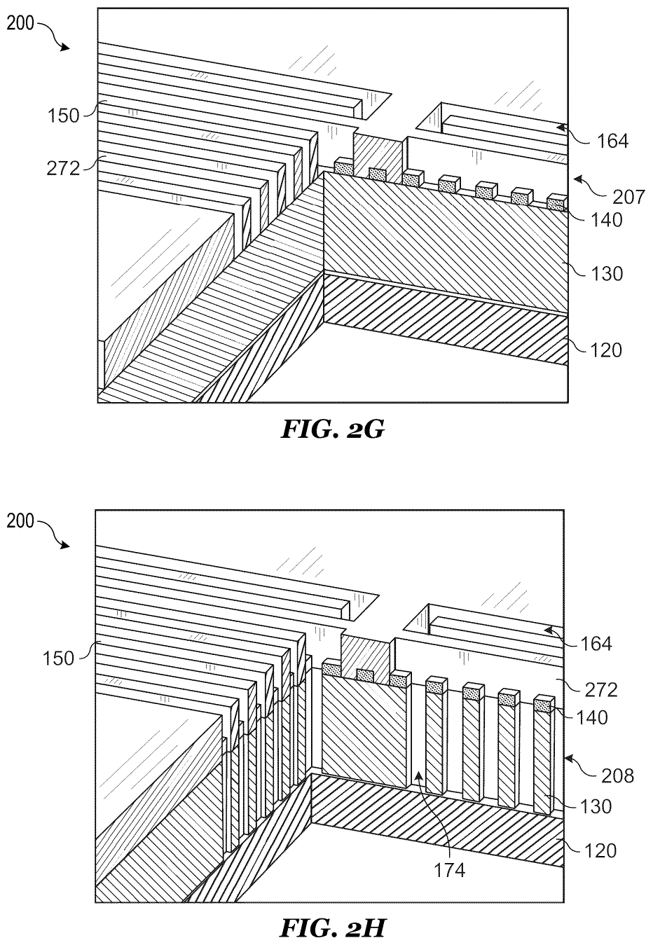

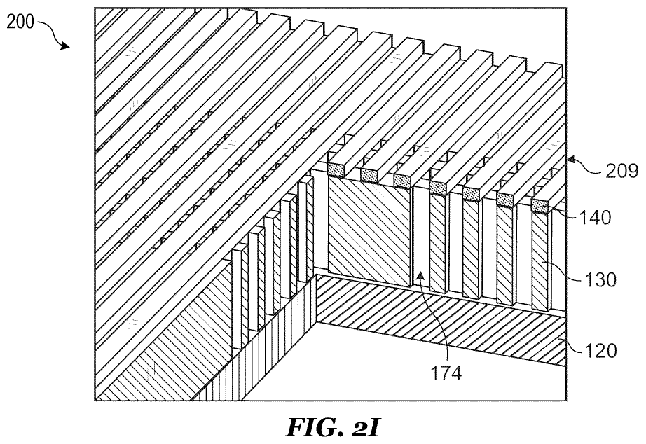

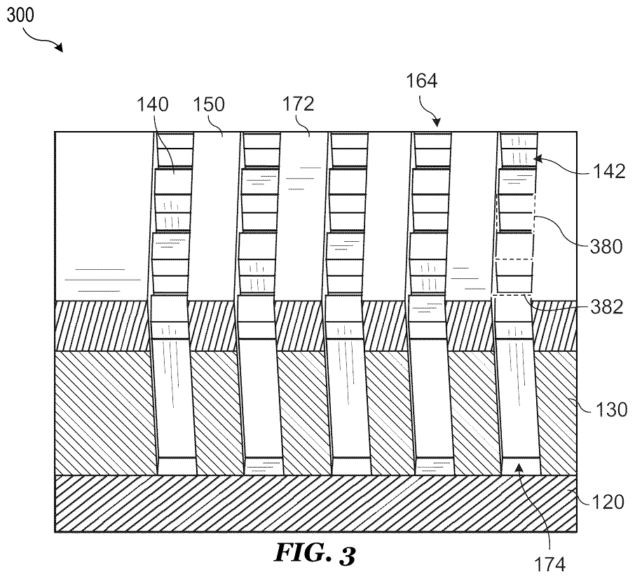

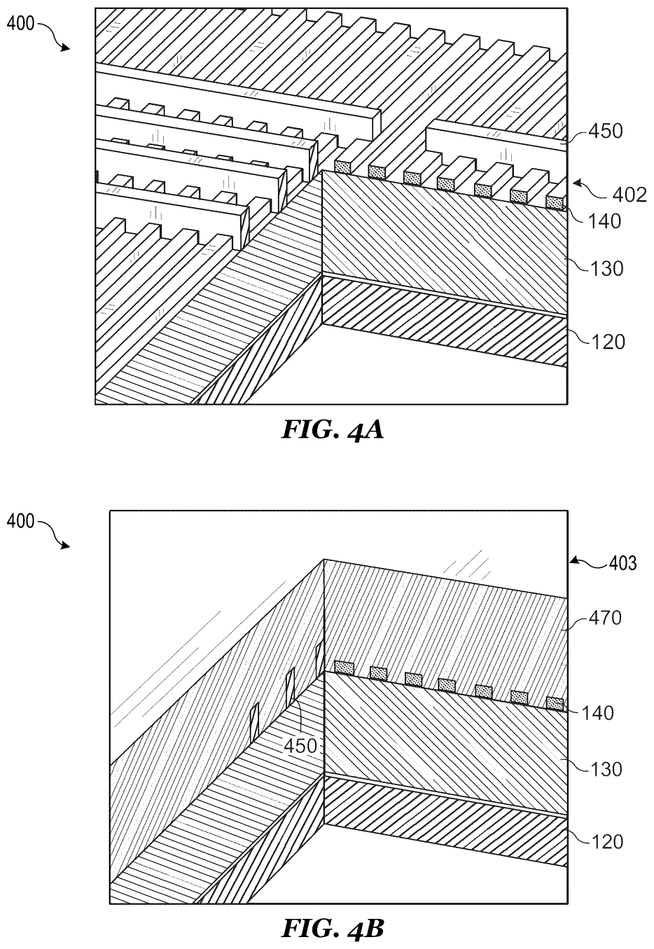

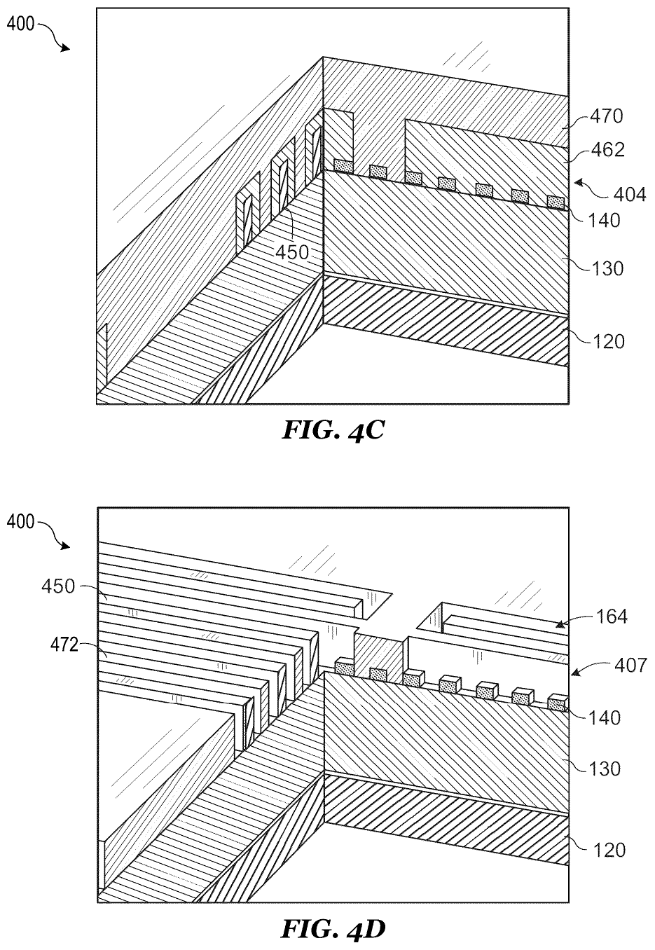

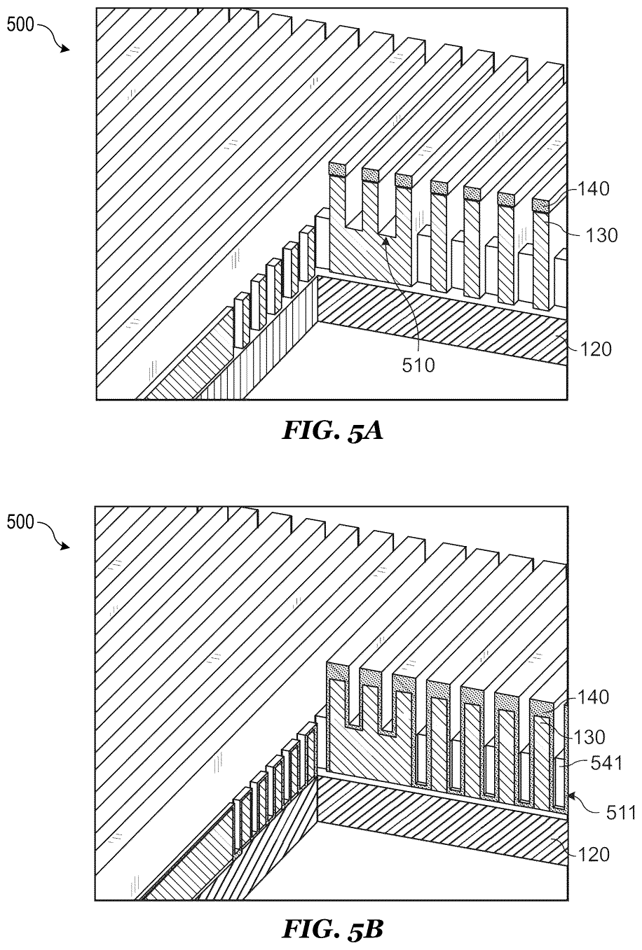

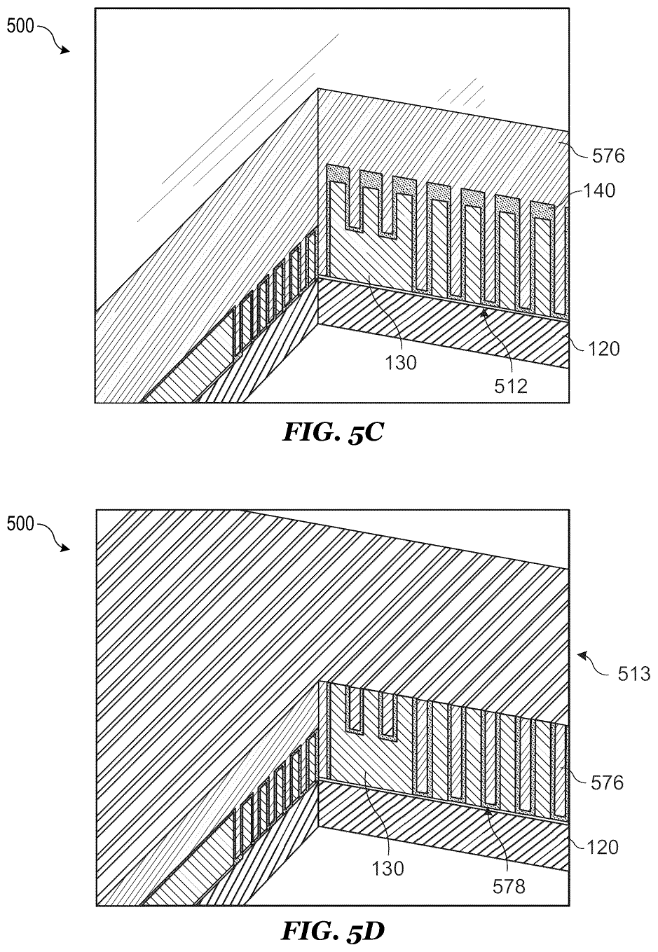

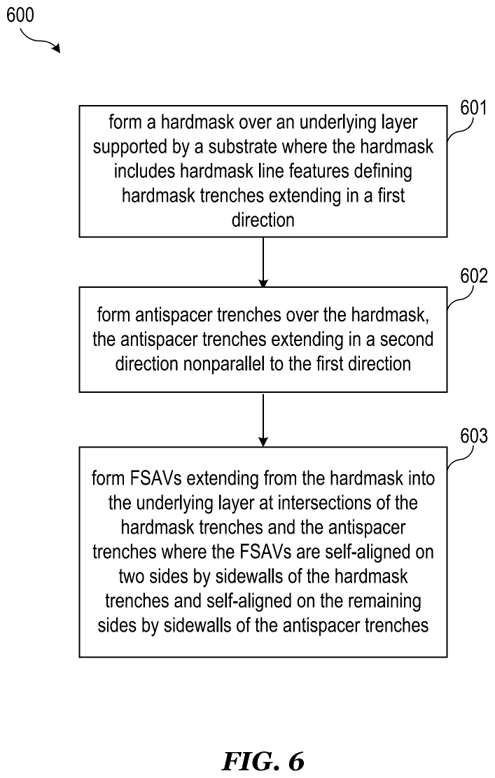

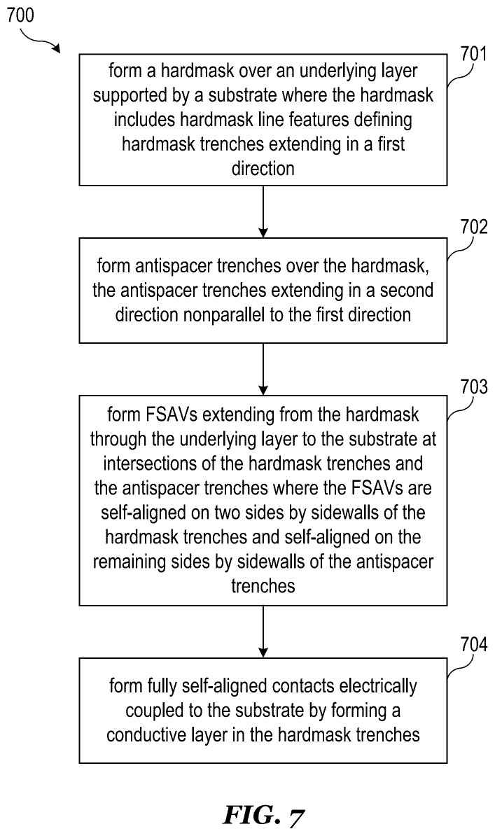

Embodiments provided below describe various structures and methods of forming vias that are self-aligned on all sides, and in particular, structures and methods of forming vias using a hardmask and antispacers. The following description describes the embodiments. FIGS. 1A and 1B are used to describe an example patterned substrate including FSAVs formed using a hardmask and antispacers. An example process flow for patterning a substrate to form FSAVs is described using FIGS. 2A-2I. FIG. 3 is used to describe an example patterned substrate that includes FSAVs. Another example process flow for patterning a substrate to form FSAVs is described using FIGS. 4A-4D while an example process flow for patterning a substrate to form FSAV contacts is described using FIGS. 5A-5D. Two example methods of patterning a substrate are described using FIGS. 6 and 7.

FIGS. 1A and 1B illustrate an example patterned substrate including fully self-aligned vias (FSAVs) passing through an underlying layer using antispacer trenches formed across hardmask trenches underlying a relief pattern and a developed overcoat where FIG. 1A shows the patterned substrate before a stripping step and FIG. 1B shows the patterned substrate after the stripping step in accordance with embodiments of the invention.

Referring to FIGS. 1A and 1B, a patterned substrate 100 includes a hardmask 140 formed over (e.g., on) an underlying layer 130, which may include various individual material layers and structures. The underlying layer 130 is supported by a substrate 120. Antispacer trenches 164 are formed over the hardmask 140 and the underlying layer 130. A relief pattern 150 and a developed overcoat layer 172 may also be formed over the hardmask 140. For example, the antispacer trenches 164 may be defined by the relief pattern 150 (e.g., a patterned photoresist) on a first side and by the developed overcoat layer 172 on an opposing second side. As shown, each of the intersections of the hardmask trenches 142 and the antispacer trenches 164 form an FSAV 174 (a fully self-aligned via).

The hardmask 140 includes hardmask line features defining hardmask trenches 142 extending in a first direction (illustrated as up and down on the page). In contrast, the antispacer trenches 164 extend in a second direction (illustrated as left and right on the page) that is nonparallel to the first direction. That is, the second direction converges with the first direction so that the antispacer trenches 164 cross over the hardmask trenches 142. While in this specific example, the second direction is shown to be substantially perpendicular to the first direction, there is no strict requirement that this be the case, the requirement instead being that the directions are not parallel.

The general geometries of the hardmask 140, the relief pattern 150, and the developed overcoat layer 172 have several representative dimensions. For the hardmask 140, the hardmask line features are separated by a hardmask pitch 144 (e.g., measured from the center of the hardmask line features, as shown). Each of the hardmask line features also has a hardmask line width 146 which, together with the hardmask pitch 144, defines a hardmask trench width 148. In this specific example (and possibly intentionally in some applications), the hardmask pitch 144 and the hardmask trench width 148 are substantially similar in width. However, this is not required, the only requirement being that both the hardmask line width 146 and the hardmask trench width 148 be nonzero (so as to define the hardmask trenches 142).

Similarly, the relief pattern 150 is defined by a relief pattern pitch 152 and a relief pattern width 156. The developed overcoat layer 172 is then defined by an overcoat width 158 and may surround some or all features of the relief pattern 150 (as shown). Of course, if the relief pattern 150 extends all the way to the edges of the patterned substrate 100, then the developed overcoat layer 172 may not surround the relief pattern 150. The developed overcoat layer 172 is separated from the relief pattern 150 by an antispacer trench width 157. As shown, the developed overcoat layer 172 may be positioned in such as way relative to the relief pattern 150 so as to define a split pitch 154 which is half that of the relief pattern pitch 152 (e.g., using an antispacer process to form the antispacer trenches 164 from the relief pattern 150, some examples of which will be subsequently described).

Each of the FSAVs 174 may be etched into the underlying layer 130 using the hardmask 140, the relief pattern 150, and the developed overcoat layer 172 as an etch mask. Because these structures are used to define the FSAVs 174 and formed on the patterned substrate 100 before forming the FSAVs 174, each FSAV 174 is self-aligned in all directions (e.g., all of the sidewalls defining a hole structure are self-aligned). For example, each FSAV 174 has an antispacer self-alignment 180 and a hardmask self-alignment 182 (shown as pairs of respective dashed lines). For the antispacer self-alignment 180, two opposing sidewalls of the FSAV 174 are defined by sidewalls of the antispacer trenches 164. In this specific example, one sidewall of the FSAV 174 (the upper sidewall for labeled antispacer self-alignment 180) is defined by a sidewall of the developed overcoat layer 172 while the opposing sidewall (e.g., lower) is defined by a sidewall of the relief pattern 150. Similarly, for the hardmask self-alignment 182, the remaining sidewalls (e.g., the right and left sidewalls) are each defined by a sidewall of the hardmask trenches 142 (i.e., sidewalls of the hardmask 140 defining the hardmask trenches 142).

In some embodiments, the whole structure of each FSAV 174 is substantially a square (illustrated as such here), but the FSAVs 174 may also be other shapes depending on the relative positioning and pitches of the hardmask trenches 142 and the antispacer trenches 164). Further, in some cases, some or all of the FSAVs 174 may have elongated shapes (e.g., rectangular, diamond, etc.). There is no requirement that all of the FSAVs 174 have the same shape. One example of a configuration where all of the FSAVs 174 are elongated would be when the hardmask trench width 148 and the antispacer trench width 157 are substantially different. An example of a case where some of the FSAVs 174 are more elongated than others would be when the hardmask 140 includes cuts in the hardmask line features.

The patterned substrate 100 may include or be in an intermediate stage of fabrication to include any manner of microelectronic devices, such as semiconductor devices. For example, various electronic components may be included on the patterned substrate 100 such as active components like transistors, gated diodes, and silicon-controlled rectifiers (SCRs), and passive components like resistors, capacitors, inductors, and diodes, which are configured using manipulation of electronic properties and parameters to perform tasks like amplification, regulation, and signal modulation. The components may be arranged in specialized circuits, some of which include memory circuits, such as random access memory (RAM), read-only memory (ROM), and flash memory, digital logic circuits including logic gates, multiplexers, decoders and encoders, flip-flops, and registers, and analog circuits such as signal processors, filters, sensors, and the like. In various embodiments, the patterned substrate 100 is or will be an integrated circuit (IC), ranging from largescale ICs, such as a microcontroller or microprocessor, so smaller, specialized ICs.

The substrate 120 may be any suitable type of substrate made of any suitable material so long as it is configured to support layers and structures formed thereon and therein. For example, the substrate may be a semiconductor substrate, a metal substrate, a dielectric substrate, or any combination thereof. In various embodiments, the substrate 120 is a semiconductor substrate, and the substrate 120 comprises silicon (Si), such as a silicon wafer in some embodiments. Other semiconductor substrates are also possible, such as germanium (Ge). The substrate 120 may also be a compound semiconductor substrate, such as gallium arsenide (GaAs), or other III-V semiconductors.

The material of the hardmask 140 is selected so that the hardmask 140 is configured to protect underlying regions of the underlying layer 130 during an etching step. In various embodiments, the hardmask 140 includes a metal, and the hardmask 140 includes a ceramic material in some embodiments, such as TiN (titanium nitride) in one embodiment, or TaN (tantalum nitride) in another embodiment. The hardmask 140 may also be carbon-based. In one embodiment, the hardmask 140 is an amorphous carbon hardmask. In other implementations, the hardmask 140 is a silicon based hardmask, such as a silicon carbide (SiC) hardmask, a silicon oxide (SiO₂) hardmask, and others. The underlying layer 130 may be a dielectric layer and is tetraethyl orthosilicate (TEOS) in one embodiment. Of course, other dielectrics are also possible such as silicon oxide (SiO₂), silicon nitride (Si₃N₄), ONO (e.g., multilayer oxide, nitride, oxide, etc.), and others.

FIGS. 2A-2I illustrate an example process flow for patterning a substrate to form FSAVs passing through an underlying layer using antispacer trenches formed across hardmask trenches where FIG. 2A shows a hardmask patterning step, FIG. 2B shows a lithography step, FIG. 2C shows an intermediate layer formation step, FIG. 2D shows an acid diffusion step, FIG. 2E shows an intermediate layer removal step, FIG. 2F shows an overcoat formation step, FIG. 2G shows a development step, FIG. 2H shows an FSAV etching step, and FIG. 2I shows a stripping step in accordance with embodiments of the invention. The process flow of FIGS. 2A-2I may be used to form the patterned substrates described herein, such as the patterned substrate of FIGS. 1A-1B, for example. Similarly labeled elements may be as previously described.

Referring to FIG. 2A, a process flow 200 for patterning a substrate begins with a hardmask patterning step 201 during which a hardmask material layer is formed (e.g., deposit, grown, attached, etc.) over an underlying layer 130 that is supported by a substrate 120. The hardmask material layer is then patterned using suitable techniques to form a hardmask 140. For example, the hardmask 140 may be patterned using a lithographic technique, such as photolithography, X-ray lithography, or even a maskless lithography such as electron beam lithography. Any suitable lithographic technique may be used, and may be chosen based on a variety of considerations including geometric considerations such as the desired pitch, critical dimension (CD), etc. as well as cost considerations (because processes yielding smaller features are typically more expensive).

The dimensionality of the hardmask 140 (e.g., pitch, CD, etc.) may be chosen to be relatively small. In order to achieve smaller features, advanced lithography techniques may be used. In various embodiments, the lithographic technique is an ultraviolet lithography process, and is a deep ultraviolet (DUV) lithography process in one embodiment, and an extreme ultraviolet (EUV) lithography process in another embodiment. The lithographic technique may be performed in an ambient air environment, but may also be performed in other environments, such as submerged in a liquid (e.g., as in immersion lithography), under low pressure (e.g., under vacuum at various pressures), in an inert environment (e.g., using a noble gas), and so on. In some cases, multiple patterning techniques may be used, such as various flavors of self-aligned multiple patterning (SAMP).

Referring now to FIG. 2B, the process flow 200 continues with a lithography step 202 during which a relief pattern 250 is formed of the hardmask 140. The relief pattern 250 may be a patterned photoresist layer that is patterned using a photolithography technique. As shown, the relief pattern 250 may include line structures that have width greater than the separation between structures. In various embodiments, the line structures of the relief pattern 250 include an acid-sensitive component (e.g., for a photoresist, the acid-sensitive component responsible for reacting with an acid from a photoacid generator (PAG) that shifts the solubility of the photoresist to form the relief pattern). The acid-sensitive component may not have reacted with an acid in the line structures of the relief pattern during lithography step 202.

It should be noted that here and in the following a convention has been adopted for brevity and clarity wherein elements adhering to the pattern [×50] where ‘x’ is the figure number may be related implementations of a relief pattern in various embodiments. For example, the relief pattern 250 may be similar to the relief pattern 150 except as otherwise stated. An analogous convention has also been adopted for other elements as made clear by the use of similar terms in conjunction with the aforementioned numbering system.

Moving to FIG. 2C, the process flow 200 continues with an intermediate layer formation step 203 during which an intermediate layer 260 is formed over the relief pattern 250. The intermediate layer 260 may any conformal material that fills the spaces between the structures of the relief pattern 250. The intermediate layer 260 is configured to act as an acid source for the relief pattern 250. For this purpose, the intermediate layer 260 includes an acid generator (e.g., a thermal acid generator (TAG), or a PAG, etc.).

Now referring to FIG. 2D, an acid diffusion step 204 of the process flow 200 is to diffuse acid from the intermediate layer 260 into outer regions of the relief pattern 250 to increase the solubility of the outer regions. That is, the outer regions become antispacers 262. For example, the intermediate layer 260 may include a TAG that is configured to release acid in response to applied thermal energy. In this case, a bake step may be used to diffuse acid generated by the TAG into the outer region to form the antispacers 262.

Turning to FIG. 2E, the process flow 200 continues with an intermediate layer removal step 205 during which the intermediate layer 260 is removed (including between the structures of the relief pattern 250, now defined by the antispacers 262) while leaving both the antispacers 262 and the remaining relief pattern 250 functionally intact. Specifically, the structural integrity of the antispacers 262 and the relief pattern 250 after the intermediate layer removal step 205 are such that they maintain continuous coverage of the underlying layer 130 in the regions defined by the original relief pattern 250.

Referring now to FIGS. 2F and 2G, the next step of the process flow 200 is an overcoat formation step 206 during which an overcoat 270 is formed between the antispacers 262 (e.g., over the antispacers 262 and the relief pattern 250 and entering the spaces between the antispacers 262). Similar to the intermediate layer 260, the overcoat 270 is a conformal material. However, the overcoat 270 is configured to be much less soluble in a developer that is used to remove the antispacers 262 in a development step 207 to form a remaining relief pattern 150 defined by a developed overcoat layer 272. After the development step 207, the supported layers of the substrate 120 include the existing structures that provide the self-aligned sides for the formation of FSAVs.

As illustrated in FIG. 2H, the process flow 200 then includes an FSAV etching step 208 where the underlying layer 130 is etched to form FSAVs 174 using the hardmask 140, the relief pattern 150, and the developed overcoat layer 272 as an etch mask. At this point, the substrate 120 and supported layers correspond to the overhead view of the patterned substrate 100, as shown in FIG. 1A. Some or all of the FSAVs 174 may extend through the underlying layer 130 to the substrate 120 below, but this is not required. For example, in some cases all of the FSAVs 174 may extend only partially through the underlying layer 130. In some cases, the surface of the substrate 120 may have topography such that some of the FSAVs 174 extend through the underlying layer 130 to reach features (e.g., raised features of the substrate 120) while others do not. Some situations where this might occur are when the intention is to make dummy vias (e.g., for security), when the hardmask 140 pattern cannot be altered to exactly match the desired vias because it is being used for another purpose (e.g., forming metal lines), or due to feature density limitations in either the formation of the hardmask trenches 142 or the antispacer trenches 164.

Referring now to FIG. 2I, the FSAVs 174 have been formed after the FSAV etching step 208 and the process flow 200 may further include a stripping step 209 that strips the relief pattern 150 and the developed overcoat layer 272 leaving only the hardmask 140 and the FSAVs 174 formed in the underlying layer 130. At this stage, the substrate 120 and supported layers correspond to the overhead view of the patterned substrate 100, as shown in FIG. 1B.

FIG. 3 shows a magnified three-dimensional (3D) view of an example patterned substrate including FSAVs passing through an underlying layer using antispacer trenches formed across hardmask trenches underlying a relief pattern and a developed overcoat in accordance with embodiments of the invention.

Referring to FIG. 3, a patterned substrate 300 includes a substrate 120 supporting an underlying layer 130 with a hardmask 140 formed thereon. A relief pattern 150 and a developed overcoat layer 172 are formed over the hardmask 140. The patterned substrate 300 may be a magnified 3D view of the patterned substrate 100 as shown in FIG. 1B corresponding with the substrate 120 after the FSAV etching step 208 of FIG. 2H. As before each FSAV 174 is full self-aligned with an antispacer self-alignment 380 and a hardmask self-alignment 382.

FIGS. 4A-4D illustrate another example process flow for patterning a substrate to form FSAVs passing through an underlying layer using antispacer trenches formed across hardmask trenches where FIG. 4A shows a lithography step, FIG. 4B shows an overcoat formation step, FIG. 4C shows an acid diffusion step, and FIG. 4D shows a development step in accordance with embodiments of the invention.

Referring to FIGS. 4A-4D, a process flow 400 for patterning a substrate begins with a lithography step 402. The lithography step 402 may be performed after a hardmask 140 is formed over an underlying layer 130 supported by a substrate 120 (e.g., after a step similar or identical to the hardmask patterning step 201 of FIG. 2A, for example). A relief pattern 450 is formed over the hardmask 140 in the lithography step 402. In contrast to the relief pattern 250 formed in the lithography step 202 (FIG. 2B), the line structures of the relief pattern 450 have a width that is smaller than the separation between structures.

In various embodiments, the relief pattern 450 includes an acid generator that has not been activated (e.g., a PAG, TAG, etc.) For example, the relief pattern 450 may be a patterned photoresist where the structures of the relief pattern 450 were not exposed during patterning (i.e., the PAG used for photopatterning is still present in the structures). Alternatively, the relief pattern 450 may be a patterned photoresist that includes another PAG that is different than the PAG used to photopatterning. Still alternatively, a TAG may be included along with the PAG used for photopatterning in the photoresist of the relief pattern 450. The process flow 400 further includes an overcoat formation step 403 where an overcoat 470 is formed over the relief pattern 450. The overcoat 470 may be similar to other overcoats, except that the overcoat 470 is configured to be acid-sensitive (e.g., by including acid-sensitive component). The acid-sensitive component may behave similarly to the acid-sensitive component in the relief pattern 250.

Acid from the relief pattern 450 may be diffused into the overcoat 470 to form antispacers 462 in an acid diffusion step 404 of the process flow 400. For example, the acid diffusion step 404 may include a bake step that supplies thermal energy facilitating diffusion of the acid into the overcoat 470. In some cases, the acid generator may be diffused and energy to activate the acid generator (i.e. to release the acid) may be supplied separately. When acid is released in the relief pattern 450 in addition to the overcoat 470, a freeze step may be required to “harden” the relief pattern 450 so that it is not removed along with the antispacers 462. However, when the activation energy of the acid generator is below the activation energy of the PAG used for photopatterning of the relief pattern 450 (when it is a patterned photoresist), a freeze step not be needed since the acid generator can be diffused and activated without approaching the activation energy threshold of the relief pattern 450.

After the acid diffusion step 404, the substrate 120 and supported layers are at a similar stage as after the overcoat formation step 206. From here, the process flow 400 then includes a development step 407 where the antispacers 462 are removed leaving the relief pattern 450 and a developed overcoat layer 472 (which may be similar to the developed overcoat layer 272 except that the specific material composition of the overcoat 470 may differ from that of the overcoat 270. After the development step 407, the substrate 120 and supported layers may be in a similar state as after the development step 207 of the process flow 200. Then, from this point FSAVs 174 may be formed starting from FSAV etching step 208 of the process flow 200, for example.

FIGS. 5A-5D illustrate an example process flow for patterning a substrate to form FSAV contacts passing through an underlying layer using antispacer trenches formed across hardmask trenches where FIG. 5A shows a trench etching step, FIG. 5B shows a barrier deposition step, FIG. 5C shows a plating step, FIG. 5D shows a planarization step in accordance with embodiments of the invention.

Referring to FIG. 5A, a process flow 500 may begin with a substrate 120 and supported layers in a similar state as after the stripping step 209 of the process flow 200, for example. The process flow 500 then includes a trench etching step 510 that forms trenches in the underlying layer 130 using the hardmask 140 as an etch mask (e.g., without a relief pattern and a developed overcoat layer over the hardmask 140, the regions of the underlying layer 130 beneath the hardmask trenches 142 are fully exposed and full trenches are etched into the underlying layer 130.

As shown, the trenches etched during the trench etching step 510 do not extend all the way through the underlying layer 130 (e.g., because then the regions at the substrate 120 between the FSAVs 174 along the hardmask trenches 142 would be exposed). The trenches formed in the trench etching step 510 may be configured to facilitate the formation of electrical contact between FSAVs 174 along a given hardmask trench 142. That is, the FSAVs 174 are self-aligned to the formed trenches allowing the electrical connection to be made without alignment error.

Now referring to FIG. 5B, the process flow 500 continues with a liner deposition step 511 during which a liner 541 is formed in the trenches and the FSAVs 174. In some cases, this step may not be needed. When included, the liner 541 may be configured to act as a barrier layer for subsequently formed material and/or as a seed layer to aid in the formation of a subsequent layer. In various embodiments, the liner 541 includes a metal and the liner 541 is a ceramic material in some embodiments. For example, in some embodiments, the liner 541 is a nitride, and is TiN (titanium nitride) in one embodiment, and is TaN (tantalum nitride) in another embodiment. The liner 541 may be the same material as the hardmask 140, but this is not required.

Turning now to FIG. 5C, the process flow 500 includes a plating step 512 where a contact layer 576 (e.g., a conductive material formed in the FSAVs 174 and the etched hardmask trenches 142, as well as over the hardmask 140 in some cases). In some embodiments, the contact layer 576 is a metal and the contact layer 576 is copper in one embodiment. When the contact layer 576 extends above the hardmask 140 (and/or to remove the hardmask 140), the process flow 500 includes a planarization step 513 where the contact layer 576 is planarized to expose the underlying layer 130 (i.e., the hardmask 140 is removed). For example, the hardmask 140 may be used as an etch stop to allow a planarization process such as a chemical mechanical polish (CMP) process to be completed at an appropriate height for the conductive lines and FSAV contacts 578 to remain intact.

FIG. 6 illustrates an example method of patterning a substrate to form FSAVs in accordance with embodiments of the invention. The method of FIG. 6 may be combined with other methods and process and may use any of the intermediate and final structures as described herein. For example, the method of FIG. 6 may be combined with any of the embodiments of FIGS. 1A-5D, and 7. Although shown in a logical order, the arrangement and numbering of the steps of FIG. 6 are not intended to be limited. The method steps of FIG. 6 may be performed in any suitable order or concurrently with one another as may be apparent to a person of skill in the art.

Referring to FIG. 6, a method 600 of patterning a substrate includes a step 601 of forming a hardmask over an underlying layer supported by a substrate. The hardmask includes hardmask line features defining hardmask trenches extending in a first direction. Antispacer trenches are formed over the hardmask in a step 602 of the method 600. The antispacer trenches extend in a second direction nonparallel to the first direction. The method 600 further includes a step 603 of forming FSAVs extending from the hardmask into the underlying layer at intersections of the hardmask trenches and the antispacer trenches. The FSAVs are self-aligned on two sides by sidewalls of the hardmask trenches and self-aligned on the remaining sides by sidewalls of the antispacer trenches.

The hardmask may have a hardmask pitch (e.g., the distance between the hardmask line features). The antispacer trenches may in turn have an antispacer pitch (e.g., the distance between the antispacer trenches). The hardmask pitch and the antispacer pitch may be substantially the same or different. The hardmask may include a metal (e.g., titanium, such as in TiN, tantalum, such as in TaN, etc.). The underlying layer may include a dielectric layer (e.g., an oxide, such as TEOS).

The step 602 of forming the antispacer trenches may include forming a relief pattern (e.g., a patterned photoresist) having a first pitch over the hardmask, forming antispacers adjacent to and physically contacting the relief pattern, forming an overcoat between the antispacers, and removing the antispacers to form antispacer trenches. For example, the sidewalls of each of the antispacer trenches may have a first sidewall defined by the relief pattern and a second sidewall defined by the overcoat.

In one embodiment, the step 602 of forming the antispacers further includes forming an intermediate layer over the relief pattern, diffusing acid from the intermediate layer into outer regions of the relief pattern to increase solubility of the outer regions (the outer regions of the relief pattern are the antispacers), and removing the intermediate layer before forming the overcoat. Alternatively, in another embodiment, the step 602 of forming the antispacers may instead include diffusing acid from the relief pattern into the overcoat to increase solubility of regions of the overcoat adjacent to the relief pattern (the adjacent regions of the overcoat are the antispacers).

FIG. 7 illustrates an example method of patterning a substrate to form FSAV contacts in accordance with embodiments of the invention. The method of FIG. 7 may be combined with other methods and performed using the systems and apparatuses as described herein. For example, the method of FIG. 7 may be combined with any of the embodiments of FIGS. 1A-6. Although shown in a logical order, the arrangement and numbering of the steps of FIG. 7 are not intended to be limited. The method steps of FIG. 7 may be performed in any suitable order or concurrently with one another as may be apparent to a person of skill in the art.

Referring to FIG. 7, a method 700 of patterning a substrate includes a step 701 of forming a hardmask over an underlying layer supported by a substrate. The hardmask includes hardmask line features defining hardmask trenches extending in a first direction. Antispacer trenches are formed over the hardmask in a step 702 of the method 700. The antispacer trenches extend in a second direction nonparallel to the first direction. The method 700 further includes a step 703 of forming FSAVs extending from the hardmask through the underlying layer to the substrate at intersections of the hardmask trenches and the antispacer trenches. The FSAVs are self-aligned on two sides by sidewalls of the hardmask trenches and self-aligned on the remaining sides by sidewalls of the antispacer trenches. The method 700 further includes a step 704 of forming fully self-aligned contacts electrically coupled to the substrate by forming a conductive layer in the hardmask trenches and the FSAVs.

The hardmask may be a TiN hardmask and the conductive layer may include copper. Forming the conductive layer may include forming a TiN liner in the hardmask trenches and over the TiN hardmask, forming the copper of the conductive layer using the TiN liner as a seed layer, and planarizing the conductive layer to expose the underlying layer using the TiN hardmask as an etch stop. The dielectric layer may include TEOS (tetraethyl orthosilicate), the substrate comprises silicon. The substrate may include a semiconductor, such as silicon. The fully self-aligned contacts may be various types of contacts. In one embodiment, the fully self-aligned contacts are source and drain contacts. In another embodiment, the fully self-aligned contacts are backside power rail contacts.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Example embodiments of the invention are summarized here. Other embodiments can also be understood from the entirety of the specification as well as the claims filed herein.

Example 1. A method of patterning a substrate, the method including: forming a hardmask over an underlying layer supported by a substrate, the hardmask including hardmask line features defining hardmask trenches extending in a first direction; forming antispacer trenches over the hardmask, the antispacer trenches extending in a second direction nonparallel to the first direction; and forming fully self-aligned vias (FSAVs) extending from the hardmask into the underlying layer at intersections of the hardmask trenches and the antispacer trenches, the FSAVs being self-aligned on two sides by sidewalls of the hardmask trenches and self-aligned on the remaining sides by sidewalls of the antispacer trenches.

Example 2. The method of example 1, where the hardmask includes a hardmask pitch and the antispacer trenches include an antispacer pitch substantially equal to the hardmask pitch.

Example 3. The method of one of examples 1 and 2, where forming the antispacer trenches over the hardmask includes: forming a relief pattern including a first pitch over the hardmask; forming antispacers adjacent to and physically contacting the relief pattern; forming an overcoat between the antispacers; and removing the antispacers to form antispacer trenches, the sidewalls of each of the antispacer trenches including a first sidewall defined by the relief pattern and a second sidewall defined by the overcoat.

Example 4. The method of example 3, where forming the antispacers includes: forming an intermediate layer over the relief pattern; diffusing acid from the intermediate layer into outer regions of the relief pattern to increase solubility of the outer regions, the outer regions being the antispacers; and removing the intermediate layer before forming the overcoat.

Example 5. The method of example 3, where forming the antispacers includes: diffusing acid from the relief pattern into the overcoat to increase solubility of regions of the overcoat adjacent to the relief pattern.

Example 6. The method of one of examples 3 to 5, where the hardmask includes a metal, the underlying layer includes a dielectric layer, the relief pattern is a patterned photoresist, and where the method further includes: forming fully self-aligned contacts electrically coupled to the substrate by forming a copper layer in the hardmask trenches and the FSAVs.

Example 7. The method of one of examples 1 to 6, where the hardmask includes a metal and the underlying layer includes a dielectric layer.

Example 8. A method of patterning a substrate, the method including: forming a hardmask over an underlying layer supported by a substrate, the hardmask including hardmask line features defining hardmask trenches extending in a first direction; forming antispacer trenches over the hardmask, the antispacer trenches extending in a second direction nonparallel to the first direction; forming fully self-aligned vias (FSAVs) extending from the hardmask through the underlying layer to the substrate at intersections of the hardmask trenches and the antispacer trenches, the FSAVs being self-aligned on two sides by sidewalls of the hardmask trenches and self-aligned on the remaining sides by sidewalls of the antispacer trenches; and forming fully self-aligned contacts electrically coupled to the substrate by forming a conductive layer in the hardmask trenches and the FSAVs.

Example 9. The method of example 8, where the hardmask is a titanium nitride (TiN) hardmask, where the conductive layer includes copper, and where forming the conductive layer includes: forming a TiN liner in the hardmask trenches and over the TiN hardmask; forming the copper of the conductive layer using the TiN liner as a seed layer; and planarizing the conductive layer to expose the underlying layer using the TiN hardmask as an etch stop.

Example 10. The method of examples 8 and 9, where the hardmask includes a hardmask pitch and the antispacer trenches include an antispacer pitch substantially equal to the hardmask pitch.

Example 11. The method of one of examples 8 to 10, where forming the antispacer trenches over the hardmask includes: forming a relief pattern including a first pitch over the hardmask; forming antispacers adjacent to and physically contacting the relief pattern; forming an overcoat between the antispacers; and removing the antispacers to form antispacer trenches, the sidewalls of each of the antispacer trenches including a first sidewall defined by the relief pattern and a second sidewall defined by the overcoat.

Example 12. The method of example 11, where forming the antispacers includes: forming an intermediate layer over the relief pattern; diffusing acid from the intermediate layer into outer regions of the relief pattern to increase solubility of the outer regions, the outer regions being the antispacers; and removing the intermediate layer before forming the overcoat.

Example 13. The method of example 11, where forming the antispacers includes: diffusing acid from the relief pattern into the overcoat to increase solubility of regions of the overcoat adjacent to the relief pattern.

Example 14. The method of one of examples 8 to 13, where the hardmask includes a metal and the underlying layer includes a dielectric layer.

Example 15. The method of example 14, where the hardmask is a titanium nitride (TiN) hardmask, the dielectric layer includes tetraethyl orthosilicate (TEOS), the substrate includes silicon, and the fully self-aligned contacts include copper.

Example 16. A patterned substrate including: a substrate; a dielectric layer disposed on the substrate; a hardmask disposed on the dielectric layer, the including hardmask line features defining hardmask trenches extending in a first direction; antispacer trenches disposed over the hardmask and the dielectric layer, each of the antispacer trenches extending in a second direction nonparallel to the first direction and being defined by a patterned photoresist on a first side and an overcoat on an opposing second side; and fully self-aligned vias (FSAVs) etched into the dielectric layer using the hardmask, the patterned photoresist, and the overcoat as an etch mask, the FSAVs being self-aligned on two sides by sidewalls of the hardmask trenches and self-aligned on the remaining sides by sidewalls of the antispacer trenches.

Example 17. The patterned substrate of example 16, where the hardmask includes a hardmask pitch and the antispacer trenches include an antispacer pitch substantially equal to the hardmask pitch.

Example 18. The patterned substrate of one of examples 16 and 17, further including: fully self-aligned contacts disposed in the FSAVs, the fully self-aligned contacts being electrically coupled to the substrate.

Example 19. The patterned substrate of example 18, where the fully self-aligned contacts are source and drain contacts.

Example 20. The patterned substrate of example 18, where the fully self-aligned contacts are backside power rail contacts.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of patterning a substrate, the method comprising:
forming a hardmask over an underlying layer supported by a substrate, the hardmask comprising hardmask line features defining hardmask trenches extending in a first direction;
forming antispacer trenches over the hardmask, the antispacer trenches extending in a second direction nonparallel to the first direction; and
forming fully self-aligned vias (FSAVs) extending from the hardmask into the underlying layer at intersections of the hardmask trenches and the antispacer trenches, the FSAVs being self-aligned on two sides by sidewalls of the hardmask trenches and self-aligned on the remaining sides by sidewalls of the antispacer trenches.

2. The method of claim 1, wherein the hardmask comprises a hardmask pitch and the antispacer trenches comprise an antispacer pitch substantially equal to the hardmask pitch.

3. The method of claim 1, wherein forming the antispacer trenches over the hardmask comprises:
forming a relief pattern comprising a first pitch over the hardmask;
forming antispacers adjacent to and physically contacting the relief pattern;
forming an overcoat between the antispacers; and
removing the antispacers to form antispacer trenches, the sidewalls of each of the antispacer trenches comprising a first sidewall defined by the relief pattern and a second sidewall defined by the overcoat.

4. The method of claim 3, wherein forming the antispacers comprises:
forming an intermediate layer over the relief pattern;
diffusing acid from the intermediate layer into outer regions of the relief pattern to increase solubility of the outer regions, the outer regions being the antispacers; and
removing the intermediate layer before forming the overcoat.

5. The method of claim 3, wherein forming the antispacers comprises:
diffusing acid from the relief pattern into the overcoat to increase solubility of regions of the overcoat adjacent to the relief pattern.

6. The method of claim 3, wherein the hardmask comprises a metal, the underlying layer comprises a dielectric layer, the relief pattern is a patterned photoresist, and wherein the method further comprises:
forming fully self-aligned contacts electrically coupled to the substrate by forming a copper layer in the hardmask trenches and the FSAVs.

7. The method of claim 1, wherein the hardmask comprises a metal and the underlying layer comprises a dielectric layer.

8. A method of patterning a substrate, the method comprising:
forming a hardmask over an underlying layer supported by a substrate, the hardmask comprising hardmask line features defining hardmask trenches extending in a first direction;
forming antispacer trenches over the hardmask, the antispacer trenches extending in a second direction nonparallel to the first direction;
forming fully self-aligned vias (FSAVs) extending from the hardmask through the underlying layer to the substrate at intersections of the hardmask trenches and the antispacer trenches, the FSAVs being self-aligned on two sides by sidewalls of the hardmask trenches and self-aligned on the remaining sides by sidewalls of the antispacer trenches; and
forming fully self-aligned contacts electrically coupled to the substrate by forming a conductive layer in the hardmask trenches and the FSAVs.

9. The method of claim 8, wherein the hardmask is a titanium nitride (TiN) hardmask, wherein the conductive layer comprises copper, and wherein forming the conductive layer comprises:
forming a TiN liner in the hardmask trenches and over the TiN hardmask;
forming the copper of the conductive layer using the TiN liner as a seed layer; and
planarizing the conductive layer to expose the underlying layer using the TiN hardmask as an etch stop.

10. The method of claim 8, wherein the hardmask comprises a hardmask pitch and the antispacer trenches comprise an antispacer pitch substantially equal to the hardmask pitch.

11. The method of claim 8, wherein forming the antispacer trenches over the hardmask comprises:
forming a relief pattern comprising a first pitch over the hardmask;
forming antispacers adjacent to and physically contacting the relief pattern;
forming an overcoat between the antispacers; and
removing the antispacers to form antispacer trenches, the sidewalls of each of the antispacer trenches comprising a first sidewall defined by the relief pattern and a second sidewall defined by the overcoat.

12. The method of claim 11, wherein forming the antispacers comprises:
forming an intermediate layer over the relief pattern;
diffusing acid from the intermediate layer into outer regions of the relief pattern to increase solubility of the outer regions, the outer regions being the antispacers; and
removing the intermediate layer before forming the overcoat.

13. The method of claim 11, wherein forming the antispacers comprises:
diffusing acid from the relief pattern into the overcoat to increase solubility of regions of the overcoat adjacent to the relief pattern.

14. The method of claim 8, wherein the hardmask comprises a metal and the underlying layer comprises a dielectric layer.

15. The method of claim 14, wherein the hardmask is a titanium nitride (TiN) hardmask, the dielectric layer comprises tetraethyl orthosilicate (TEOS), the substrate comprises silicon, and the fully self-aligned contacts comprise copper.

16. A patterned substrate comprising:
a substrate;
a dielectric layer disposed on the substrate;
a hardmask disposed on the dielectric layer, the comprising hardmask line features defining hardmask trenches extending in a first direction;
antispacer trenches disposed over the hardmask and the dielectric layer, each of the antispacer trenches extending in a second direction nonparallel to the first direction and being defined by a patterned photoresist on a first side and an overcoat on an opposing second side; and
fully self-aligned vias (FSAVs) etched into the dielectric layer using the hardmask, the patterned photoresist, and the overcoat as an etch mask, the FSAVs being self-aligned on two sides by sidewalls of the hardmask trenches and self-aligned on the remaining sides by sidewalls of the antispacer trenches.

17. The patterned substrate of claim 16, wherein the hardmask comprises a hardmask pitch and the antispacer trenches comprise an antispacer pitch substantially equal to the hardmask pitch.

18. The patterned substrate of claim 16, further comprising:
fully self-aligned contacts disposed in the FSAVs, the fully self-aligned contacts being electrically coupled to the substrate.

19. The patterned substrate of claim 18, wherein the fully self-aligned contacts are source and drain contacts.

20. The patterned substrate of claim 18, wherein the fully self-aligned contacts are backside power rail contacts.
